(19) United States
(12) Patent Application Publication
(10) Pub. No.: US 2025/0029844 A1
(43) Pub. Date: Jan. 23, 2025

(54) COPPER FEATURES AND RELATED METHODS OF FORMING

(71) Applicant: SEMICONDUCTOR COMPONENTS INDUSTRIES, LLC, Scottsdale, AZ (US)

(72) Inventor: Michael J. SEDDON, Gilbert, AZ (US)

(73) Assignee: SEMICONDUCTOR COMPONENTS INDUSTRIES, LLC, Scottsdale, AZ (US)

(21) Appl. No.: 18/355,171

(22) Filed: Jul. 19, 2023

(51) Int. Cl. H01L 21/48; H01L 23/373

(52) U.S. Cl. CPC H01L 21/4807; H01L 23/3735

(57) ABSTRACT

Implementations of a method of forming a copper feature may include providing a copper layer with a thickness thicker than 1 mm; cutting a trench partially through the thickness leaving a remaining thickness using a laser; and, after cutting, removing the remaining thickness using a water jet.

### BACKGROUND

### 1. Technical Field

Aspects of this document relate generally to semiconductor packages. More specific implementations involve systems and methods for forming copper features.

### 2. Background

Semiconductor packages have been devised that work to provide electrical and mechanical connections with a motherboard or other circuit board. Various semiconductor packages also work to provide protection from humidity or electrostatic discharge for semiconductor die included int the semiconductor packages.

### SUMMARY

Implementations of a method of forming a copper feature may include providing a copper layer with a thickness thicker than 1 mm; cutting a trench partially through the thickness leaving a remaining thickness using a laser; and, after cutting, removing the remaining thickness using a water jet.

Implementations of a method of forming a copper feature may include one, all, or any of the following:

The method may include coupling the copper layer with a dielectric substrate.

The dielectric substrate may include one of aluminum oxide or boron nitride.

The method may further include forming a layer over the copper layer prior to lasering and removing the layer after cutting.

The method may include reducing copper oxide in the copper layer by exposing the copper layer to a forming gas.

The copper layer may be a first copper layer and the method further may include coupling a second metal layer with a thickness thicker than 1 mm to the dielectric substrate; cutting a trench partially through the thickness of the second metal layer leaving a remaining thickness of the second metal layer using the laser; and, after lasering, cutting through the remaining thickness of the second metal layer using the water jet.

The copper layer may be a first copper layer and the method further may include coupling a heat sink including a second metal layer with a thickness thicker than 1 mm to the dielectric substrate; cutting a trench partially through the thickness of the second metal layer leaving a remaining thickness of the second metal layer using the laser; and, after lasering, cutting into the remaining thickness of the second metal layer using the water jet to form a fin of the heat sink.

Implementations of a method of forming a copper feature may include providing a copper layer with a thickness thicker than 1 mm; cutting a trench partially through the thickness leaving a remaining thickness using a water jet; and, after cutting, etching through the remaining thickness.

Implementations of a method of forming a copper feature may include one, all, or any of the following:

The method may include coupling the copper layer with a dielectric substrate.

The dielectric substrate may be may include one of aluminum oxide or boron nitride.

The method may further include forming a layer over the copper layer prior to lasering and removing the layer after etching.

The method may include reducing copper oxide in the copper layer by exposing the copper layer to a forming gas.

The copper layer may be a first copper layer and the method further may include coupling a second metal layer with a thickness thicker than 1 mm to the dielectric substrate; cutting a trench partially through the thickness of the second metal layer leaving a remaining thickness of the second metal layer using the water jet; and, after cutting, etching through the remaining thickness of the second metal layer.

The copper layer may be a first copper layer and the method further may include coupling a heat sink including a second metal layer with a thickness thicker than 1 mm to the dielectric substrate and cutting a trench partially through the thickness of the second metal layer leaving a remaining thickness of the second metal layer using the water jet to form a fin of the heat sink.

Implementations of a method of forming an insulated copper feature may include providing a copper layer including a thickness; forming a plurality of trenches through the thickness; and permanently filling the plurality of trenches with at least one polymer material immediately after forming the plurality of trenches.

Implementations of a method of forming an insulated copper feature may include one, all, or any of the following:

The method may include coupling the copper layer with a dielectric substrate.

Permanently filling the trenches further may include printing the at least one polymer material into the plurality of trenches.

The at least one polymer material may extend above the thickness of the copper layer.

The method may include coupling a thinned semiconductor die to the copper layer where the at least one polymer material extends around one or more edges of the thinned semiconductor die.

The method may include a submodule to the copper layer where the at least one polymer material extends around one or more edges of the submodule.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of a copper layer during cutting with a laser, removal of a protective layer, coupling with a dielectric substrate, and following etching of a remaining thickness of the copper layer;

FIG. 2 is a side cross sectional view of a copper layer during cutting with a laser, coupling with a dielectric substrate, cutting of a remaining thickness of the copper layer with a water jet, and removal of a protective layer coupled to the copper layer;

FIG. 3 is a side cross sectional view of a copper layer during cutting with a water jet after coupling with a dielectric substrate, after removal of a protective layer, and after etching of a remaining thickness of the copper layer;

FIG. 4 is an implementation of an integrated semiconductor substrate with semiconductor die coupled thereto;

FIG. 5 is an implementation of a semiconductor package with spacers and semiconductor die coupled thereto;

FIG. 6 is an implementation of a semiconductor package with semiconductor die and wirebonds that includes a ball grid array;

FIG. 7 is an implementation of a semiconductor package with an integrated substrate comprising a heat sink being formed by lasering;

FIG. 8 is an implementation of a copper layer coupled to a dielectric substrate;

FIG. 9 illustrates the copper layer of FIG. 8 following forming of features therein through forming a plurality of trenches therein;

FIG. 10 illustrates the copper layer of FIG. 9 following application of a polymer material into the plurality of trenches;

FIG. 11 illustrates the copper layer of FIG. 10 following coupling of a thinned semiconductor die thereto;

FIG. 12 illustrates another implementation of a copper layer following application of a polymer material into the plurality of trenches;

FIG. 13 illustrates the copper layer of FIG. 12 following coupling of a semiconductor die thereto;

FIG. 14 illustrates another implementation of a copper layer following application of a polymer material into the plurality of trenches;

FIG. 15 illustrates the copper layer of FIG. 14 following coupling of a semiconductor die thereto;

FIG. 16 illustrates another implementation of a copper layer following application of a first polymer material and a second polymer material into a plurality of trenches; and

FIG. 17 illustrates another implementation of a copper layer following application of a polymer material into a plurality of trenches and coupling of submodules thereto.

### DESCRIPTION

This disclosure, its aspects and implementations, are not limited to the specific components, assembly procedures or method elements disclosed herein. Many additional components, assembly procedures and/or method elements known in the art consistent with the intended copper features and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such copper features and related methods, and implementing components and methods, consistent with the intended operation and methods.

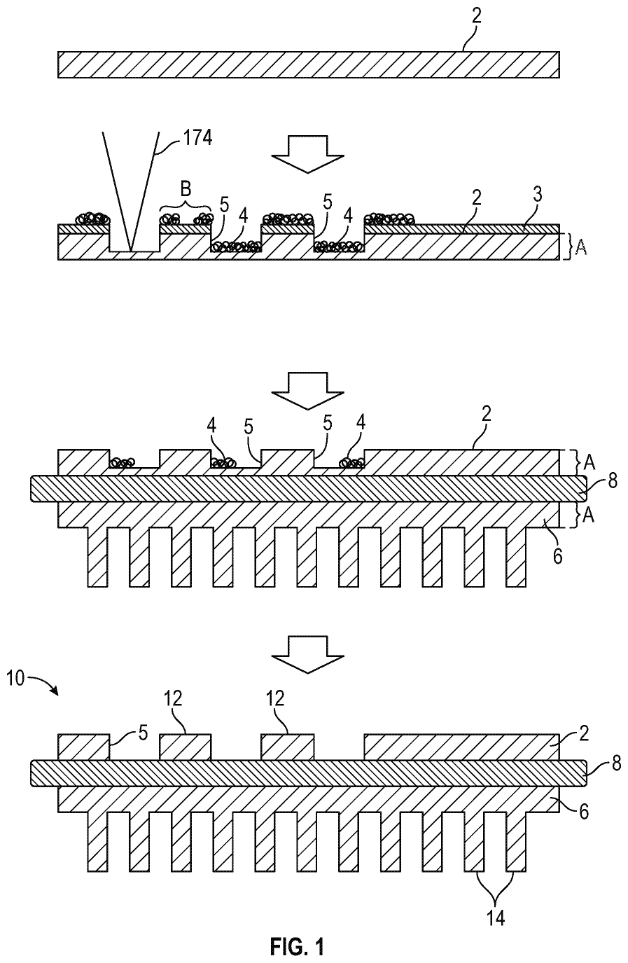

Referring to FIG. 1, an implementation of a copper layer 2 is illustrated. In the various implementations disclosed herein the copper layer is greater than 1 millimeters in thickness, which poses a significant challenge for forming traces and features therein and therethrough using etching only because of the amount of material required to be removed to form a feature. The various method implementations disclosed herein are designed to assist with formation of features in such thick copper layers. In various implementations, the copper layer 2 may be a standalone film; in other implementations the copper layer 2 may be already coupled to a dielectric substrate. However, in the method implementation illustrated in FIG. 1, the copper layer 2 is a standalone film. FIG. 1 then illustrates the copper layer 2 following application of protective layer 3 thereon during cutting/lasering using laser beam 174. As illustrated, slag 4 in the form of melted copper and material from the protective layer 3 is present on both sides of the trenches 5 and in the bottom of the trenches after the cutting process. In various implementations the protective layer may be formed of a resin material, such as, by non-limiting example, the resin material marketed under the tradename HOGOMAX by Disco Corporation of Tokyo, Japan. In other implementations, the material may be a flux, a polyimide material, a photoresist, a metal film separate from the copper layer such as, by non-limiting example, titanium, titanium tungsten, HOGOMAX, or any combination of the foregoing.

The copper layer 2 has a thickness 7, but the laser cutting process does not remove all of the copper from within each trench, leaving a remaining thickness of the copper layer at the bottom of each of the trenches. The value/amount of the remaining thickness may depend on consideration of various factors, including, by non-limiting example, the degree of mechanical stability desired for the copper layer 2 post-cutting, the amount of slag produced during the cutting process, an economical run rate of the cutting process, the material characteristics of the copper layer, or any other economic or mechanical consideration. Also, as illustrated in FIG. 1, a certain minimum distance B is maintained between each of the trenches (forming a minimum width or head B of each of the copper features being formed). This minimum width/head B may be determined by a minimum bottom measure (trench bottom width) that needs to be maintained to ensure successful etching/formation of the copper feature in various implementations. In the various method implementations disclosed herein, pure copper may be used, by any other copper alloy could also be processed.

FIG. 1 illustrates the copper layer 2 next after it has been coupled to a dielectric substrate 8. In various implementations, the substrate may be formed of, by non-limiting example, aluminum oxide, aluminum nitride, boron nitride, FR4, or any other ceramic or dielectric material capable of mechanically supporting the copper layer. For those implementations employing boron nitride, the substrate may be a sheet of epoxy resin that include boron nitride particles as filler. The coefficient of thermal expansion of this implementation of dielectric substrate may be about 17-19 ppm and thermal conductivity may be about 16.5 W/K which may enable comparable or better thermal resistance performance to the ceramic dielectric layer materials disclosed previously in this document. In various implementations, because the dielectric substrate may be made of a sheet of epoxy resin, the layer is flexible enough to allow it to be folded in half/folded back onto itself. Such a dielectric material is quite different from the rigid ceramic dielectric layer materials previously discussed in this document and thus has significant mechanical flexibility advantages. For example, the use of the boron nitride-containing dielectric layer may enable the use of common mold compounds with CTEs of about 14-17 ppm for the molding process which may lower the overall package cost. Also, the boron nitride-containing dielectric layer may demonstrate higher thermal conductivity and breakdown voltage than a ceramic dielectric material containing aluminum oxide or aluminum nitride.

Here, as illustrated, in FIG. 1, the copper layer 2 after being coupled to the dielectric substrate 8 forms an integrated substrate that has a heat sink 6 coupled thereto. Note that, as illustrated in FIG. 1, the thickness 7, A of the copper layer 2 matches or substantially matches a thickness A of the largest planar portion of the heat sink 6. In this way, warpage of the copper layer 2 and dielectric substrate 8 can be minimized during operation and during manufacture. While the implementation in FIG. 1 illustrates the use of the method in the context of an integrated substrate, the various method implementations disclosed herein can also be used in conjunction with any of a wide variety of substrate types, including, by non-limiting example, direct bonded copper (DBC) substrates, integrated metal substrates (IMS), or any other substrate type. FIG. 1 also illustrates how that the protective layer 3 has been removed along with a majority of the slag 4 but some slag 4 remains in the trenches 5. Where the material of the protective layer is a resin, the removal process may take place using water or deionized water. Where the material of the protective layer is a polyimide or photoresist, the removal process may involve a solvent stripping/washing process or an ashing process. Where the material of the protective layer includes a separate metal layer, if the metal layer is titanium or titanium tungsten, the use of wet etching using hydrogen peroxide or hydrogen fluoride may be employed to remove the metal layer and the remaining copper slag. A wide variety of removal processes may be selected depending on the material(s) present in the protective layer.

FIG. 1 illustrates in the final drawing the integrated substrate 10 following etching of the remaining thickness of the plurality of trenches 5 to form traces/features 12 formed of copper now coupled on the dielectric substrate 8. In various method implementations, the etching is carried out using wet etching using various chemistries that are capable of etching copper. FIG. 1 also illustrates how the heat sink 6 includes various fins/pins 14 that serve to increase the surface area of the heat sink 6 and improve heat transfer from the ultimately assembled semiconductor package.

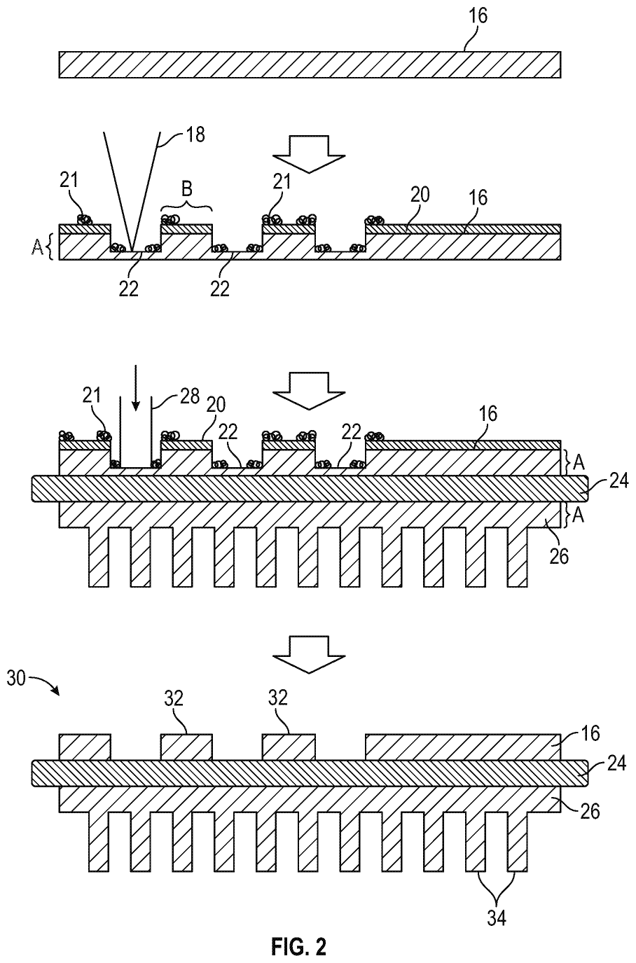

Referring to FIG. 2, a set of drawings detailing a copper layer 16 following processing using an implementation of a method of forming copper features is illustrated. The copper layer 16 may be any disclosed in this document and in this case is a copper film. FIG. 2 illustrates the copper layer 16 following cutting using laser beam 18 after application of protective film 20. The material of the protective film 20 may be any disclosed in this document. As illustrated in FIG. 2, slag 21 from the lasering process is deposited around the trenches 22 being formed into the material of the copper layer 16. FIG. 2 also illustrates how the laser beam cutting process does not cut all the way through the thickness A of the copper layer 16 but leaves a remaining thickness at the bottom of each of the trenches 22. Also, depending on the particular method implementation, a minimum width/head distance B may be maintained between trench edges to ensure proper subsequent processing. However, where removal of the remaining thickness of the copper layer 16 does not take place using etching, the need to maintain the minimum width/head distance B may not be needed or as critical.

FIG. 2 also illustrates the cut copper layer 16 following coupling with a dielectric substrate 24 to which a heat sink 26 has also be coupled, forming an integrated substrate similar in structure to that disclosed in the implementation illustrated in FIG. 1. The heat sink 26 may be any heat sink type disclosed in this document and the dielectric substrate 24 may be any substrate type disclosed in this document. FIG. 2 illustrates how, following cutting using laser beam 18, water jet 28 is used to cut the remaining thickness of the copper layer 16 to finish forming the copper features coupled to the dielectric substrate 24. Note also in FIG. 2 that, similar to the integrated substrate implementation of FIG. 1, the thickness A of the copper layer 16 is the same as or substantially the same as the thickness A of the largest planar portion of the heat sink 26 to help prevent/reduce warpage of the dielectric substrate 24.

In the final figure of FIG. 2, the integrated substrate 30 is illustrated following removal of the protective layer 20 and the remaining slag 21 with it, leaving the copper features 32 of the copper layer 16 on one side of the dielectric substrate 24 with the heat sink 26 coupled to the other side of the dielectric substrate. Also as illustrated in FIG. 2, the heat sink 26 includes various pins/fins 34 used to increase the surface area of the heat sink 26 and the corresponding heat transfer rate. The materials used for the heat sinks disclosed herein may be any of a wide variety of thermally conductive materials, including, by non-limiting example, pure copper, a copper alloy, a metal, or any other thermally conductive material. In various implementations, the material of the heat sink may be the same as the copper features to aid in matching coefficients of thermal expansion between the copper features and the heat sink during operation and avoiding warpage/stresses in the finally formed package.

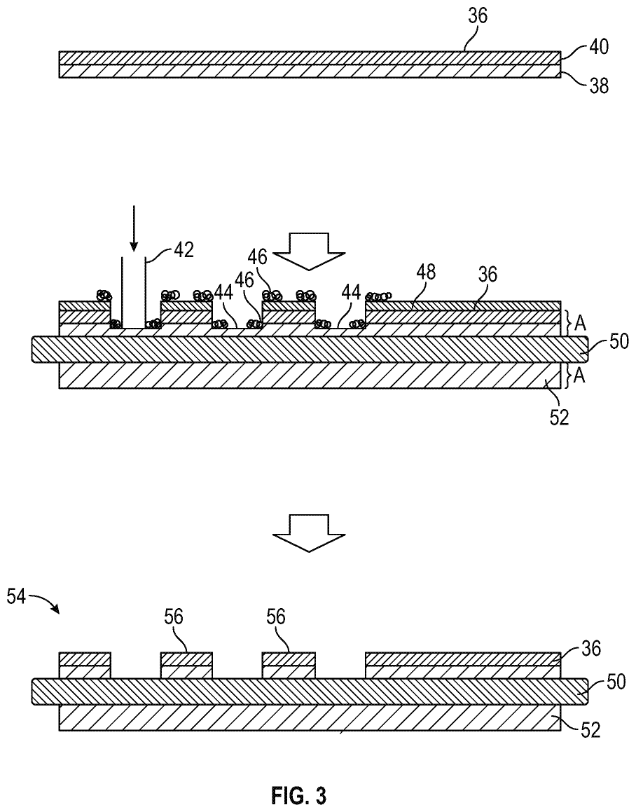

Referring to FIG. 3, an implementation of a copper-containing layer 36 is illustrated that contains a copper layer 38 and one or more metal layers 40 coupled thereto. The one or more layers 40 may include any of a wide variety of metals including, by non-limiting example, copper, nickel, titanium, tungsten, palladium, gold, silver, tin, any combination thereof, or any other electrically conductive material. FIG. 3 also illustrates how water jet 42 is used to directly form trenches 44 and that slag 46 is deposited in the bottoms of trenches 44 and on top of protective layer 48. The protective layer 48 may be made of any material and formed using any method for forming a protective layer disclosed in this document.

As previously discussed, the water jet 42 does not remove the full thickness A of the copper-containing layer 36 but leaves a remaining thickness amount to allow the copper-containing layer 36 to be coupled to dielectric layer 50 (if cut previous to coupling to the dielectric layer). In other implementations, however, where the copper-containing layer 36 is coupled to the dielectric layer 50 prior to the cutting process using the water jet, the method implementation still includes partially cutting through the copper-containing layer 36 to leave a remaining thickness. As illustrated in FIG. 3, a second copper layer 52 is coupled to the side of the dielectric layer 50 opposite that to which the cooper-containing layer 36 is coupled. In this way the resulting substrate is a direct bonded copper substrate and any of the methods of coupling the second copper layer 52 and copper-containing layer 36 with the particular material of the dielectric layer 50 may be used in various method implementations, including, by non-limiting example, sintering, bonding, gluing, thermal compression bonding, brazing, active metal brazing, or any other method of coupling the particular material of the dielectric layer 50 with the two metal layers 36, 52. The material of the dielectric layer 40 may be any dielectric material disclosed in this document. As illustrated in FIG. 3, the thickness A of the copper-containing layer 36 and the thickness A of the second copper layer 52 may be the same or substantially the same.

FIG. 3 also illustrates a direct bonded copper substrate 54 following removal of the protective layer 48 and etching of the remaining thickness of the copper-containing layer 36 to form traces 56. The removal of the protective layer 48 may take place using any method disclosed herein consistent with the material of the protective layer. The etching of the remaining thickness may take place using any method of removing copper or the material of the one or more layers of metal 40 disclosed herein or consistent with removal of the particular metal in the one or more layers of metal. In various method implementations, the etching may take place prior to the removal of the protective layer 40; in other implementations, the protective layer 40 may be removed first followed by the etching of the remaining thickness in the trenches. The resulting direct bonded copper substrate 54 has various copper-containing features/traces 56 formed thereon and is ready for additional processing to form a finished semiconductor package.

In the various method implementations disclosed thus far, the copper material may be pure copper and so following etching, there may be a need to reduce copper oxide that has formed on the traces during the processing steps. In various method implementations, reducing the copper oxide may take place through exposing the copper features to a reducing atmosphere like a forming gas to reduce any copper oxide to copper prior to additional processing. In other implementations, the one or more metal layers applied to the copper layer may be layers that can be used to protect the copper layer from oxidation during processing and be removed with an etch step before processing to prevent formation of copper oxide prior to wirebonding, for example. The material of such one or more layers may be, by non-limiting example, titanium or titanium tungsten.

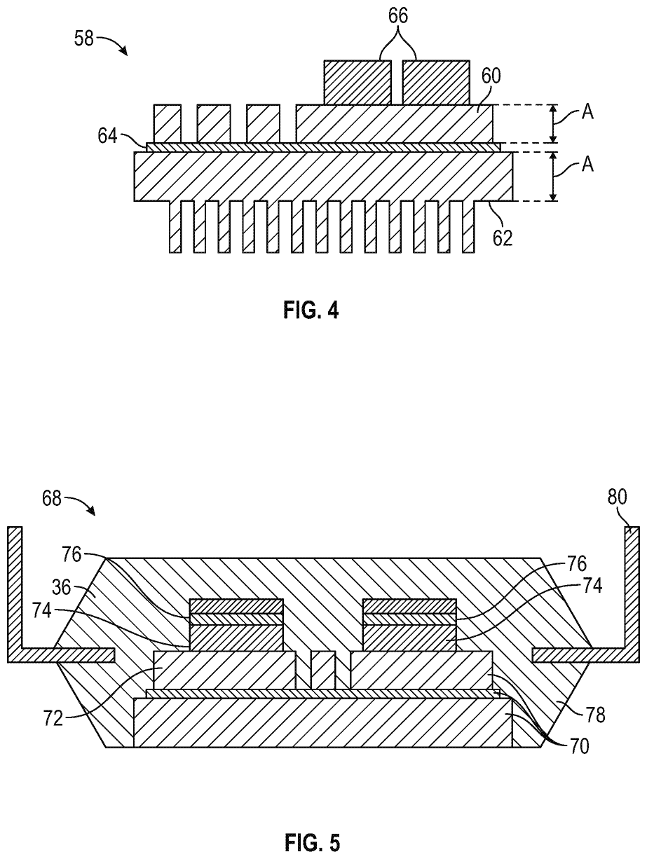

Referring to FIG. 4, an implementation of an integrated substrate 58 is illustrated that includes copper features 60, a heat sink 62, and a dielectric layer 64. This substrate 58 is illustrated at a subsequent step in package formation where semiconductor die 66 have been bonded/attached to the copper feature 60. The substrate 58 can then continue through additional processing steps as desired to allow for formation of additional interconnects to the semiconductor die 66, addition of a mold compound if an air cooled package, or other protective layers (if an immersion cooled package) as part of the remainder of the packaging process. FIG. 5 illustrates an implementation of a package 68 that contains a direct bonded copper substrate 70 with copper features 72 formed using the method implementations disclosed herein to which spacers 74 and thinned semiconductor die 76 have been attached. Encapsulant 78 has been applied to form the outer surface of the package and electrical connectors/pins 80 extend out of the encapsulant 78.

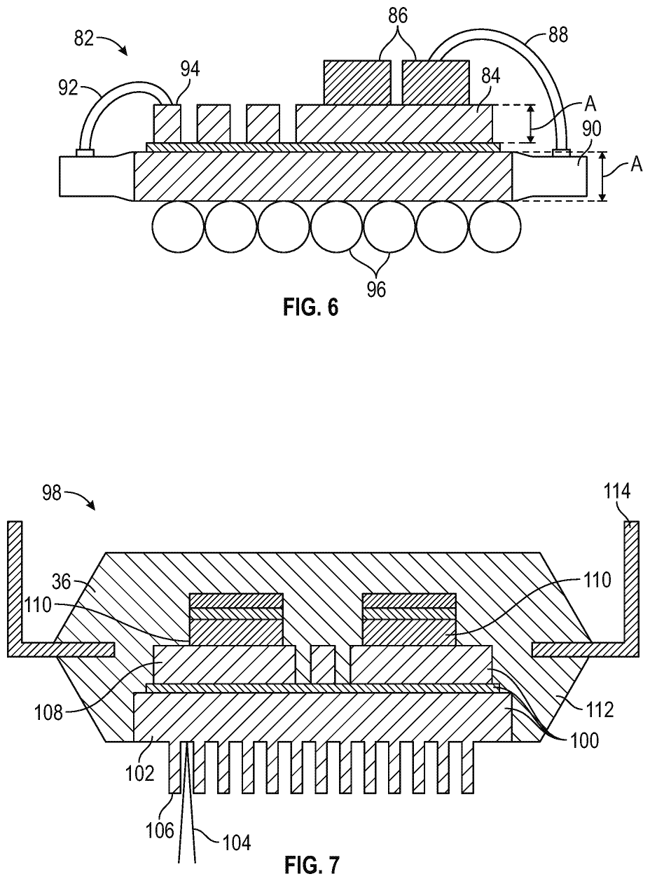

The various method implementations disclosed herein can be used with a wide variety of other semiconductor package types as well. FIG. 6 illustrates a semiconductor package 82 prior to application of a mold compound/encapsulant which shows copper features 84 formed using the method implementations disclosed herein with die 86 coupled thereto showing bond wire 88 electrically coupling die 86 to the second layer 90 of the substrate 82 and bond wire 92 electrically coupling copper feature 94 to the second layer 90 of the substrate 82. In various implementations, the second layer 90 of the substrate may be a single layer of metal or may be an interposer or redistribution layer allowing for electrical signal routing out to the ball grid array 96 illustrated in FIG. 6. Referring to FIG. 7, a semiconductor package 98 that includes an integrated substrate 100 is illustrated during formation of heat sink 102 using laser beam 104, indicating that the fins/pins 106 of the heat sink 102 can be formed as a final step in the package formation rather than during processing of the substrate itself in various method implementations. This semiconductor package 98 similarly includes copper features 108 formed using the method implementations disclosed herein to which semiconductor die 110 have been attached and enclosed with encapsulant/mold compound 112 with pins 114 extending therefrom. These non-limiting examples demonstrate how the principles disclosed herein can be utilized with a wide variety of substrate types and a wide variety of package configurations.

Furthermore, the semiconductor die utilized in the implementations disclosed in this document may include/be any of a wide variety of semiconductor device types, including, by non-limiting example, transistors, diodes, power devices, metal oxide field effect transistors (MOSFETs), insulated gate bipolar transistors (IGBTs), high-electron-mobility transistors (HEMTs), thyristors, rectifiers, or any other semiconductor device type. The various semiconductor die in this document may include a semiconductor substrate material that may be, by non-limiting example, silicon, silicon carbide, silicon on insulator, gallium arsenide, ruby, sapphire, or any other semiconductor material type.

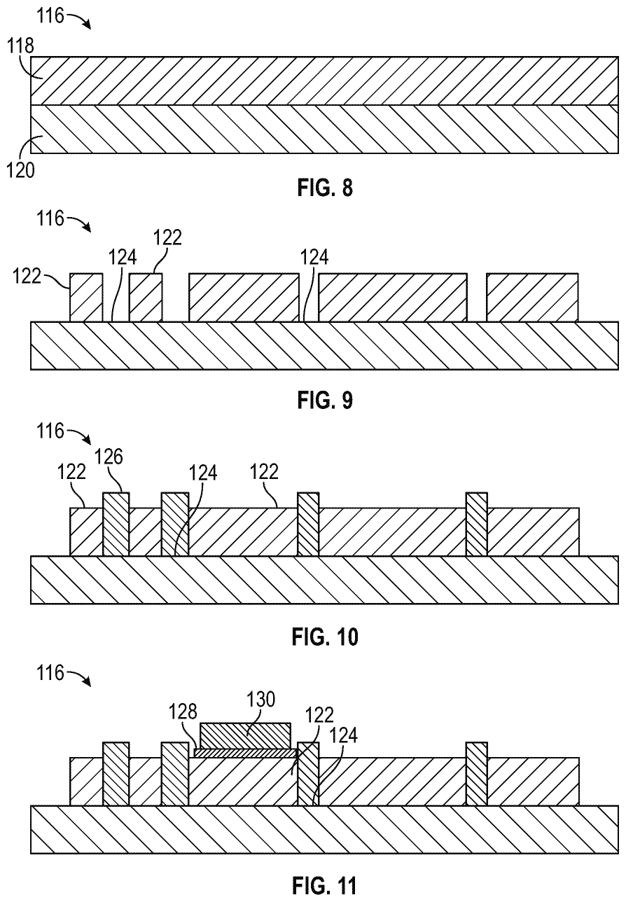

Referring to FIG. 8, an implementation of a substrate 116 with a thick copper layer 118 coupled with a dielectric layer 120 is illustrated. The thick copper layer 118 has a thickness 1 mm or greater like those previously disclosed in this document and may include any composition disclosed herein. The dielectric layer may be any dielectric material disclosed in this document including a resin material like FR4 or other laminated material. While the substrate 116 is illustrated with just a single layer of metal thereon, any of the substrate implementations disclosed subsequently here may include a second metal layer (as in the case of a direct bonded copper substrate or integrated metal substrate) or a heat sink (in the case of an integrated substrate). The substrate may also include an interposer or redistribution layer in various implementations.

FIG. 9 illustrates the substrate 116 following formation of various copper features/traces 122 from the copper layer 118. The copper features 122 may be formed using any of the methods previously disclosed in this document capable of forming such features from the thick copper layer, including various combinations thereof, including, by non-limiting example, laser-only, laser+water jet, laser+etch, water jet-only, or water jet+etch. The ability to use laser and water jet removal techniques with thick copper layers like those disclosed herein permits the formation of tighter/smaller pitches between the copper features 122. As the pitch between the copper features decreases, the aspect ratio of the trenches 124 correspondingly increases. Thus, smaller particles are capable of causing bridging or shorting defects between the copper features during operation/testing. This issue may be particularly relevant where processes like sintering are employed in subsequent packaging steps where increased levels of particulates are present. Also, where particles are present, ions in materials in the semiconductor package will migrate to the particles causing an increase in electrically conductive material at the particles which can cause shorting and bridging (which may be observed through failures at a high temperature reverse bias [HTRB] test). Furthermore, as die and other devices are coupled using electrically conductive die attach materials or solders the likelihood that an excess of the material could cause bridging between two copper features increases, thus resulting in scrap of the entire substrate.

FIG. 10 illustrates the substrate 116 following formation of an electrically insulative material 126 into each of the trenches 124. The formation process may take place through printing the electrically insulative material 126, overmolding followed by grinding, squeegeeing, stencil printing, or any other technique capable of accurately placing the electrically insulative material into the trenches leaving the copper features 122 exposed for further packaging processing steps. The electrically insulative material 126 may be, by non-limiting example, an encapsulant, a mold compound, a resin, an epoxy, spin on glass, a glass, a polymer material, or another flowable dielectric material capable of being cured/dried in place within the trenches 124. As illustrated in FIG. 10 the upper level of the electrically insulative material 126 rises above the upper planar surface/bonding surface of the various copper features 122.

Referring to FIG. 11, the substrate 116 is illustrated following bonding of a semiconductor die 130 to copper feature 122 using a solder material 128. Note that in the implementation, the raised electrically insulative material 126 prevented flow of the solder 128 into trench 124 which could have potentially caused a short between the adjacent copper features 122. Thus the ability of the electrically insulative material 126 to be raised above the level of the surface of the copper features 122 may provide greater process latitude during subsequent processing steps. Furthermore, where the semiconductor die 130 is a thinned semiconductor die, FIG. 11 illustrates how the material of the electrically insulative material extends around the edges of the semiconductor die 130. This may help, depending on the tolerance, to help reinforce/protect the edges of the thinned semiconductor die during subsequent processing operations and/or operate as a dam to prevent contact by other materials subsequently applied during packaging operations with the edges of the thinned semiconductor die. In some implementations, the raised electrically insulative material 126 may be used to “self-align” semiconductor die to a desired position when they are placed over the die attach material during chip shooting and subsequent curing operations to help mitigate die float and/or die tilt. In such implementations, the raised electrically insulative material may be present around all sides of the semiconductor die or may be present only at the corners or a subset of the corners of the semiconductor die.

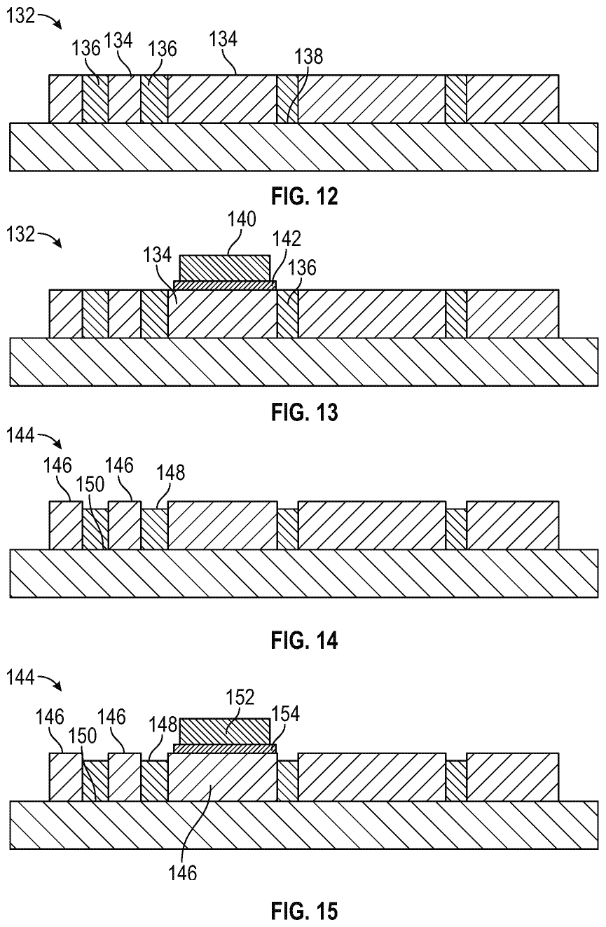

Referring to FIG. 12, another implementation of a substrate 132 is illustrated following formation of copper features 134 and formation of electrically insulative material 136 into the trenches 138. In this method implementation, the electrically insulative material is flush or substantially flush with the largest planar surface/upper surface/bonding surface of the copper features 134. This may be accomplished through precisely metering the amount of electrically insulative material dispensed/printed into the trenches 138 or through overmolding followed by grinding in various implementations. FIG. 13 illustrates the substrate 132 following bonding of a semiconductor die 140 to copper feature 134 using die attach material 142. Note that the die attach material comes up to but does not cross over the material of the electrically insulative material 136 due to surface tension forces or other material incompatibility forces that kept the die attach material 142 from bridging over to an adjacent copper feature 134. This ability may involve the selection of electrically insulative materials and die attach materials that have this type of material/surface tension/surface energy relationship with each other. In other implementations, however, the die attach material 142 may flow over the electrically insulative material 136, but the flow may be slowed significantly due to the change in material from the copper feature 134 to the electrically insulative material 136 thus preventing the formation of a bridge between adjacent copper features 134.

FIG. 14 illustrates a substrate 144 following formation of copper features 146 and formation of electrically insulative material 148 into trenches 150. Note that the level of the electrically insulative material 148 in the trenches 150 in this implementation is below the top surface/bonding surface of the copper features 146. In this method implementation, this may be accomplished by ensuring less material is dispensed/printed into the trenches 150 that is needed to fill the trenches or through selectively etching back the electrically insulative material 146 following dispensing. The particular etching chemistry and technique (dry/wet) will depend on what is needed to remove the particular electrically insulative material employed. FIG. 15 illustrates the substrate 144 following bonding of a semiconductor die 152 to copper feature 146 using die attach material 154 which may be any disclosed in this document. FIG. 15 illustrates how the surface tension of the edge of the copper feature 146 may be sufficient to keep the die attach material 154 from flowing down in to the trench 150, however, where such flow would occur, the surface energy of the material of the electrically insulative material 148 may be selected to be such that the flow of the die attach material 154 is along and against the edge of the copper feature (into and out of the page) rather than across the electrically insulative material 148, thus preventing bridging from occurring.

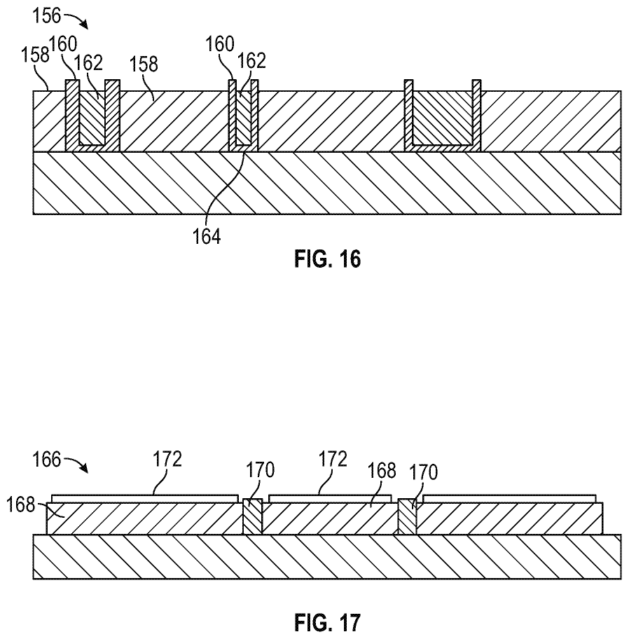

Referring to FIG. 16, a substrate 156 is illustrated that includes copper features 158. While the foregoing examples of electrically insulative materials have included a single material, multiple layers of the same or different electrically insulative material(s) may be employed. The substrate 156 implementation illustrated in FIG. 16 utilizes two different materials that form a first layer 160 formed conformally into trench 164 followed by a second layer 162 formed into the first layer 160. In these implementations, as illustrated, only one of the layers may extend above the top surface/bonding surface of the copper features 158. However, in other implementations both layers may be flush with or below the top surface/bonding surface. In implementations where multiple layers are employed, the first layer may be formed using a deposition/spray process that coats the sides of the trenches and is then stabilized while the second layer may be formed using a printing/dispensing/squeegee process like that previously disclosed. The deposition process for the first layer 160 may involve chemical vapor deposition or sputtering in some implementations.

Referring to FIG. 17, an implementation of a substrate 166 is illustrated that includes a set of copper features 168 with electrically insulative material 170 formed therein using any method disclosed in this document. The electrically insulative material 170 is raised above the largest planar surface of the copper features 168. As illustrated, die submodules 172 have been bonded to the copper features 168 and the electrically insulative material 170 now extends around and adjacent to (or against in some implementations) the edges of the die submodules 172. The die submodules 172 may include one or more die bonded together using a leadframe or clip which is itself covered by a mold compound or encapsulant allowing them to be electrically connected through various exposed pads/connectors with the material of the copper features 168. In this way, the copper features 168 can function like a leadframe or redistribution layer for the die submodules 172. In various implementations combinations of semiconductor die and die submodules bonded to the copper features may be constructed using the principles disclosed in this document.

In places where the description above refers to particular implementations of copper features and implementing components, sub-components, methods and sub-methods, it should be readily apparent that a number of modifications may be made without departing from the spirit thereof and that these implementations, implementing components, sub-components, methods and sub-methods may be applied to other copper features.

What is claimed is:

1. A method of forming a copper feature comprising:
providing a copper layer with a thickness thicker than 1 mm;
cutting a trench partially through the thickness leaving a remaining thickness using a laser; and
after cutting, removing the remaining thickness using a water jet.

2. The method of claim 1, further comprising coupling the copper layer with a dielectric substrate.

3. The method of claim 2, wherein the dielectric substrate is comprises one of aluminum oxide or boron nitride.

4. The method of claim 1, further comprising:
forming a layer over the copper layer prior to lasering; and
removing the layer after cutting.

5. The method of claim 1, further comprising reducing copper oxide in the copper layer by exposing the copper layer to a forming gas.

6. The method of claim 2, wherein the copper layer is a first copper layer and the method further comprises:
coupling a second metal layer with a thickness thicker than 1 mm to the dielectric substrate;
cutting a trench partially through the thickness of the second metal layer leaving a remaining thickness of the second metal layer using the laser; and
after lasering, cutting through the remaining thickness of the second metal layer using the water jet.

7. The method of claim 2, wherein the copper layer is a first copper layer and the method further comprises:
coupling a heat sink comprising a second metal layer with a thickness thicker than 1 mm to the dielectric substrate;
cutting a trench partially through the thickness of the second metal layer leaving a remaining thickness of the second metal layer using the laser; and
after lasering, cutting into the remaining thickness of the second metal layer using the water jet to form a fin of the heat sink.

8. A method of forming a copper feature comprising:
providing a copper layer with a thickness thicker than 1 mm;
cutting a trench partially through the thickness leaving a remaining thickness using a water jet; and
after cutting, etching through the remaining thickness.

9. The method of claim 8, further comprising coupling the copper layer with a dielectric substrate.

10. The method of claim 9, wherein the dielectric substrate is comprises one of aluminum oxide or boron nitride.

11. The method of claim 8, further comprising:
forming a layer over the copper layer prior to lasering; and
removing the layer after etching.

12. The method of claim 8, further comprising reducing copper oxide in the copper layer by exposing the copper layer to a forming gas.

13. The method of claim 9, wherein the copper layer is a first copper layer and the method further comprises:
coupling a second metal layer with a thickness thicker than 1 mm to the dielectric substrate;
cutting a trench partially through the thickness of the second metal layer leaving a remaining thickness of the second metal layer using the water jet; and
after cutting, etching through the remaining thickness of the second metal layer.

14. The method of claim 9, wherein the copper layer is a first copper layer and the method further comprises:
coupling a heat sink comprising a second metal layer with a thickness thicker than 1 mm to the dielectric substrate; and
cutting a trench partially through the thickness of the second metal layer leaving a remaining thickness of the second metal layer using the water jet to form a fin of the heat sink.

15. A method of forming an insulated copper feature comprising:
providing a copper layer comprising a thickness;
forming a plurality of trenches through the thickness; and
permanently filling the plurality of trenches with at least one polymer material immediately after forming the plurality of trenches.

16. The method of claim 15, further comprising coupling the copper layer with a dielectric substrate.

17. The method of claim 15, wherein permanently filling the trenches further comprises printing the at least one polymer material into the plurality of trenches.

18. The method of claim 15, wherein the at least one polymer material extends above the thickness of the copper layer.

19. The method of claim 18, further comprising coupling a thinned semiconductor die to the copper layer where the at least one polymer material extends around one or more edges of the thinned semiconductor die.

20. The method of claim 18, further comprising a submodule to the copper layer where the at least one polymer material extends around one or more edges of the submodule.
